(19) United States
(12) Patent Application Publication
(10) Pub. No.: US 2011/0115038 A1
(43) Pub. Date: May 19, 2011

(54) PHYSICAL QUANTITY SENSOR, ELECTRONIC DEVICE, AND METHOD OF MANUFACTURING PHYSICAL QUANTITY SENSOR

(75) Inventor: Kei KANEMOTO, Suwa (JP)

(73) Assignee: SEIKO EPSON CORPORATION, Tokyo (JP)

(21) Appl. No.: 12/944,215

(22) Filed: Nov. 11, 2010

(30) Foreign Application Priority Data
Nov. 19, 2009 (JP) 2009-263651
Jul. 23, 2010 (JP) 2010-165586

(51) Int. Cl. H01L 29/84; H01L 21/302

(52) U.S. Cl. 257/418; 438/52; 257/E29.324; 257/E21.214

(57) ABSTRACT

A physical quantity sensor includes: the fixed arm section includes a first side surface insulating film disposed on a side surface of the laminate structure, a first side surface conductor film disposed on a surface of the first side surface insulating film, and a first connection electrode section provided to the upper insulating layer, and electrically connected to the first side surface conductor film, the movable arm section includes a second side surface insulating film disposed on a side surface of the laminate structure, a second side surface conductor film disposed on a surface of the second side surface insulating film, and a second connection electrode section provided to the upper insulating layer, and electrically connected to the second side surface conductor film, and the first side surface conductor film and the second side surface conductor film are disposed so as to be opposed to each other.

The entire disclosure of Japanese Patent Application Nos: 2009-263651, filed Nov. 19, 2009 and 2010-165586, filed Jul. 23, 2010 are expressly incorporated by reference herein.

### BACKGROUND

1. Technical Field

The present invention relates to a physical quantity sensor such as a micro-electro-mechanical sensor (a MEMS sensor), a method of manufacturing a physical quantity sensor, an electronic device equipped with a physical quantity sensor, and so on.

2. Related Art

A capacitive MEMS sensor as a physical quantity sensor manufactured using a semiconductor manufacturing technology is described in, for example, JP-A-7-301640 (Document 1). In such a MEMS sensor there is generally used a structure made of silicon (Si). Since the silicon is not an insulating material, a constituent portion with silicon used consecutively is electrically conductive. Therefore, in order for detecting capacitance, electrical separation by some measure is required.

Use of silicon-on-insulator (SOI) substrates makes it easy to electrically isolate a plurality of parts constituting the structure from each other (see, e.g., JP-A-2007-150098 (Document 2)). Further, there can also be cited a method of providing, for example, trench isolation to an ordinary silicon substrate to thereby electrically separate the parts required to be isolated from each other (see, e.g., JP-T-2002-510139 (Document 3) (the term “JP-T” as used herein means a published Japanese translation of a PCT patent application)).

In Document 2, as shown in FIG. 12, movable electrode D1 and fixed electrodes D2, D3 each made of a silicon layer are surrounded by a trench T reaching a buried insulating layer (a buried oxide film) of an SOI substrate to thereby be spatially and electrically separated from a fixation frame section F as a fixation section. The fixed electrode D2 is disposed on the side where the inter-electrode gap is narrowed in accordance with the movement of the movable electrode D1 toward one direction. In contrast, the fixed electrode D3 is disposed on the side where the inter-electrode gap is widened in accordance with the movement of the movable electrode D1 toward the one direction. Regarding the layout of the fixed electrodes D2, D3, since the fixed electrodes D2, D3 themselves are each formed of a silicon layer, it is not achievable to set the fixed electrodes D2, D3 to electrical potentials different from each other. Therefore, it is required to dispose the fixed electrode D2 on one side, and the fixed electrode D3 on the other side across the movable electrode D1 in a separate manner. Therefore, as shown in FIG. 13, it is not achievable to dispose both of the fixed electrodes D2, D3 having the respective electrical potentials different from each other on both sides across the movable electrode D1. As described above, the MEMS sensor described in Document 2 becomes to have an arrangement with extremely poor area efficiency, and as a result, the chip area increases. Further, in Document 2, since the movable electrode D1 and the fixed electrodes D2, D3 are each a silicon layer, there arises a problem that even if they are highly doped, the resistance values are inferior to those of metals, and the impedance thereof becomes higher. Further, in the case of providing the trench isolation to the silicon substrate as in the case of the MEMS sensor described in Document 3, the manufacturing process of the MEMS sensor might be complicated.

### SUMMARY

An advantage of some aspects of the invention is to provide a MEMS sensor and a method of manufacturing the MEMS sensor allowing a wiring layout with a lot of flexibility, in which the fixation section and the fixed electrode are not fixed to a single type of electrical potential, and using metal layers as the conductive portions of both of the movable electrode and the fixed electrodes to thereby make it possible to realize low impedance.

According to an aspect of the invention, there is provided a physical quantity sensor including a fixation frame section, an elastically deformable section, a movable weight section coupled to the fixation frame section via the elastically deformable section and having a hollow section formed in a periphery, a fixed electrode section fixed to the fixation frame section and including a fixed electrode as one of electrodes of a capacitance element, a movable electrode section including a movable electrode moving integrally with the movable weight section, disposed so as to be opposed to the fixed electrode section, and constituting the other of the electrodes of the capacitance element, wherein the fixed electrode section includes a first laminate structure including a silicon layer, an upper insulating film, and an upper conductor layer formed so as to project from the fixation frame section, a first side surface insulating film formed on a side surface of the first laminate structure along the projection direction, a first side surface conductor film as the fixed electrode formed on the first side surface insulating film, and a first connection electrode section formed so as to include the upper conductor layer of the first laminate structure and electrically connected to the first side surface conductor film, and the movable electrode section includes a second laminate structure including the silicon layer, the upper insulating film, and the upper conductor layer formed to project from the movable weight section and to be opposed to the fixed electrode section, a second side surface insulating film formed on a side surface of the second laminate structure along the projection direction, and opposed to the first side surface conductor film, a second side surface conductor film as the movable electrode formed on the second side surface insulating film, and a second connection electrode section formed of the upper conductor layer of the second laminate structure and electrically connected to the second side surface conductor film.

Further, according to another aspect of the invention, there is provided a physical quantity sensor including a fixation section, an elastically deformable section, a movable weight section coupled to the fixation section via the elastically deformable section, a fixed arm section, and a movable arm section extending from the movable weight section, and disposed so as to be opposed to the fixed arm section, wherein the fixed arm section and the movable arm section are each a laminate structure obtained by stacking an upper insulating layer on a semiconductor layer, the fixed arm section includes a first side surface insulating film disposed on a side surface of the laminate structure, a first side surface conductor film disposed on a surface of the first side surface insulating film, and a first connection electrode section provided to the upper insulating layer, and electrically connected to the first side surface conductor film, the movable arm section includes a second side surface insulating film disposed on a side surface of the laminate structure, a second side surface conductor film disposed on a surface of the second side surface insulating film, and a second connection electrode section provided to the upper insulating layer, and electrically connected to the second side surface conductor film, and the first side surface conductor film and the second side surface conductor film are disposed so as to be opposed to each other.

The physical quantity sensor according to the aspect of the invention is manufactured by processing the silicon layer, the upper insulating film, and the upper conductor layer formed on the substrate using the semiconductor manufacturing technology, for example. Further, the MEMS sensor of the aspect of the invention has the fixation frame section (the fixation section), the movable weight section supported by the elastically deformable section and capable of moving in the detection axis direction, and the capacitance element (the variable capacitor) for detecting the physical quantity (e.g., acceleration) of the detection object.

The capacitance element (the variable capacitor) includes (is provided with at least a pair of fixed and movable electrode sections) the fixed electrode section fixed to the fixation frame section, and the movable electrode section (the movable arm section) disposed so as to be opposed to the fixed electrode section (fixed arm section) and moving integrally with the movable weight section. The movable electrode section is formed so as to project from the movable weight section. The fixed electrode section has, for example, the first structure formed by processing the silicon layer on the substrate, the upper insulating film (the upper insulating layer), and the upper conductor layer, the first side surface insulating film provided (e.g., formed so as to cover the side surface) to the side surface (the side surface on at least the side opposed to the movable electrode section) along the projection direction of the first structure, the first side surface conductor film as the fixed electrode formed on the first side surface insulating film, and the first connection electrode section formed of the upper conductor layer of the first laminate structure and electrically connected to the first side surface conductor film. Further, the movable electrode section has, for example, the second structure formed by processing the silicon layer on the substrate, the upper insulating film, and the upper conductor layer, the second side surface insulating film provided (e.g., formed so as to cover the side surface) to the side surface (the side surface on at least the side opposed to the fixed electrode section) along the projection direction of the second structure, the second side surface conductor film as the movable electrode formed on the second side surface insulating film, and the second connection electrode section formed of the upper conductor layer of the second laminate structure and electrically connected to the second side surface conductor film. It should be noted that the first side surface conductor film can also be referred to as a first side surface conductor, or a first sidewall conductor. Similarly, the second side surface conductor film can also be referred to as a second side surface conductor, or a second sidewall conductor.

Although the side surface conductor films (the first side surface conductor film and the second side surface conductor film) as the capacitance electrodes are formed on the side surfaces of the respective two insulating structures (the first laminate structure covered with the first side surface insulating film and the second laminate structure covered with the second side surface insulating film), the side surfaces being opposed to each other, the path for applying direct-current bias between the capacitance electrodes or the path for taking out the detection signal is not assured only by this structure, and therefore, in this aspect the first connection electrode section is disposed on the first laminate structure, and similarly the second connection electrode section is disposed on the second laminate structure.

Since the first connection electrode section is electrically connected to the first side surface conductor film as the fixed electrode, it is possible to apply the bias voltage to the first side surface conductor film as the fixed electrode via the first connection electrode section. Further, in the case in which the fixed electrode is an output electrode of the detection signal, it is possible to take out the detection signal via the first connection electrode section. Since the base member of the first laminate structure is formed of the silicon layer, and can be made to be the insulating structure by covering the side surface thereof with the first side surface insulating film, it is possible to provide the first connection electrode section so as to be isolated from the silicon layer in the first laminate structure. Therefore, unlike the fixed electrode formed of the silicon layer itself separated from the fixation frame section as in the case of Document 2, it becomes possible to take out the different potential by the wiring line of the first connection electrode section from the fixed electrode section to the side of the fixation frame section, which improves the area efficiency.

Since the second connection electrode section is electrically connected to the second side surface conductor film as the movable electrode, it is possible to apply the bias voltage to the second side surface conductor film as the movable electrode via the second connection electrode section. Further, in the case in which the movable electrode is an output electrode of the detection signal, it is possible to take out the detection signal via the second connection electrode section. Since the second laminate structure is formed of the silicon layer, and can be made to be the insulating structure by covering the side surface thereof with the second side surface insulating film, it is possible to provide the second connection electrode section so as to be isolated from the silicon layer.

According to the structure of the aspect of the invention, the capacitance electrodes (the fixed electrode and the movable electrode) of the capacitance element are composed of the conductor films formed on the side surfaces of the respective insulating structures (the first laminate structure covered with the first side surface insulating film and the second laminate structure covered with the second side surface insulating film). The fixed electrode and the movable electrode each have the insulating structure as the base, and are therefore electrically isolated from each other by their nature. Further, use of the insulating structures makes it easy to dispose a plurality of wiring wires in an electrically isolated manner, and even in the case of disposing other electrodes (electrodes other than the capacitance electrodes) such as connection electrodes, the electrical isolation between the electrodes can be assured. Therefore, the special device for electrically separating the different conductors used in the case of, for example, the silicon based MEMS sensor (e.g., Document 2) becomes unnecessary, and therefore, the manufacturing process can be prevented from being complicated. Further, since the structures can be manufactured using an ordinary semiconductor manufacturing technology such as isotropic etching of silicon, an increase in cost can be prevented. Further, for example, the gap (electrode distance) between the capacitance electrodes is determined in accordance with the thickness of the insulating film and the conductor film formed on the sidewall thereof after patterning (anisotropic etching of the silicon) of the laminate structure, and therefore, it is possible to sufficiently narrow the gap between the capacitance electrodes without depending only on the patterning accuracy. This feature is advantageous for improving the sensitivity of a sensor, and leads to reduction of the chip area.

In one aspect of the physical quantity sensor of the invention, the area of the fixation frame section of the physical quantity sensor can be formed using the substrate having the silicon layer at least on the lower insulating film. According to this configuration, in the elastically deformable section and an area of at least one movable electrode, the lower insulating film is removed, and a part of the hollow section can be formed. Further, owing to the lower insulating film, the silicon layer of the fixation frame section can be isolated from the outside.

Further, in one aspect of the physical quantity sensor of the invention, the fixation section includes the semiconductor layer and the upper insulating layer, an intermediate layer is disposed on the opposite side to the surface of the semiconductor layer on which the upper insulating layer is disposed, a substrate is disposed on the surface of the intermediate layer on the opposite side to the semiconductor layer side, and a hollow section is disposed between the substrate and the movable weight section and between the substrate and the movable arm section. Further, owing to the lower insulating layer, the silicon layer of the fixation frame section can be isolated from the outside.

In one aspect of the physical quantity sensor of the invention, for example, a silicon-on-insulator (SOI) substrate having the silicon layer on the silicon substrate via buried insulating layer as the intermediate layer can be used as the substrate. According to this configuration, in the space between the elastically deformable section and the silicon substrate, and between at least one movable electrode and the silicon substrate, the buried insulating layer is removed, and a part of the hollow section can be formed.

Further, in one aspect of the physical quantity sensor of the invention, the intermediate layer is different in material from the upper insulating layer. By, for example, using the material with a high etching rate as the intermediate layer, and the material with a low etching rate as the upper insulating layer, the lower insulating layer and the upper insulating layer can selectively be etched without using the resist in the manufacturing process of the physical quantity sensor, and therefore, the physical quantity sensor having the hollow section can be manufactured without making the manufacturing process complicated.

In one aspect of the physical quantity sensor of the invention, the first connection electrode section can include a first upper insulating film formed of the upper insulating film of the first laminate structure, a first internal conductor formed of the upper conductor layer disposed inside the first upper insulating film, and a first connection conductor adapted to cover an internal wall surface of the first laminate structure provided with a first contact hole formed so as to expose at least a part of a surface of the first internal conductor, to cover the surface of the first internal conductor exposed to the first contact hole, and to be connected to the first side surface conductor film as the fixed electrode.

Further, according to another aspect of the physical quantity sensor of the invention, a contact hole is provided to the upper insulating layer, the first connection electrode section is provided to an inner bottom surface of the contact hole, and the first connection electrode section and the first side surface conductor film are connected to each other via the contact hole.

In these aspects of the invention, the first internal conductor as the first connection electrode section is formed so as to be buried in the first upper insulating film of the first laminate structure, and the first internal conductor is electrically connected to the first side surface conductor film via the first connection conductor. The first connection conductor is a contacting conductor for assuring the electrical connection between the first internal conductor as the first connection electrode section and the first side surface conductor film, and for example, covers the inside wall surface of the first laminate structure provided with the first contact hole as a contact hole formed so as to expose at least a part of the surface of the first internal conductor, covers the surface of the first internal conductor exposed to the first contact hole, and is connected to the first side surface conductor film as the fixed electrode. Specifically, in the case in which the conductor layer (the first internal conductor) as the first connection electrode section is buried in the first laminate structure, the first contact hole (also referred to as a via hole or a through hole) for exposing at least a part of the surface of the first internal conductor buried therein is formed, the contacting conductor (the first connection conductor) covering the bottom surface (i.e., the surface of the first internal conductor thus exposed) and the inside wall surface of the first contact hole and having contact with the first side surface conductor film is formed, thereby realizing the electrical connection between the conductor layer (the first internal conductor) as the first connection electrode section and the first side surface conductor film as the fixed electrode.

As an advantage of the case of adopting the connection structure described above, for example, when depositing the first connection conductor, a thick film can be formed inside the contact hole, thus the connection between the respective sections (i.e., the first side surface conductor film, the first connection conductor, and the first internal conductor) can surely be assured, large contact areas between the conductors can be obtained, and it becomes easy to assure the margin (positional margin or the like) in the manufacturing process. Further, since the proven semiconductor manufacturing process using the contact holes can be used, the connection structure described above also has an advantage that it is superior in stability of manufacturing process.

In another aspect of the physical quantity sensor of the invention, the second connection electrode section can include a second upper insulating film formed of the upper insulating film of the second laminate structure, a second internal conductor formed of the conductor layer disposed inside the second upper insulating film, and a second connection conductor adapted to cover an internal wall surface of the second laminate structure provided with a second contact hole formed so as to expose at least a part of a surface of the second internal conductor, to cover the surface of the second internal conductor exposed to the second contact hole, and to be connected to the first side surface conductor film as the fixed electrode.

In another aspect of the physical quantity sensor of the invention, a contact hole is provided to the upper insulating layer, the second connection electrode section is provided to an inner bottom surface of the contact hole, and the second connection electrode section and the second side surface conductor film are connected to each other via the contact hole.

In these aspects of the invention, the second internal conductor as the second connection electrode section is formed so as to be buried in the second upper insulating film of the second laminate structure, and the second internal conductor is electrically connected to the second side surface conductor film via the second connection conductor. The second connection conductor is a contacting conductor for assuring the electrical connection between the second internal conductor as the second connection electrode section and the second side surface conductor film, and for example, covers the inside wall surface of the second laminate structure provided with the second contact hole as a contact hole formed so as to expose at least a part of the surface of the second internal conductor, covers the surface of the second internal conductor exposed to the second contact hole, and is connected to the second side surface conductor film as the movable electrode. Specifically, in the case in which the conductor layer (the second internal conductor) as the second connection electrode section is buried in the second laminate structure, the second contact hole (also referred to as a via hole or a through hole) for exposing at least a part of the surface of the second internal conductor buried therein is formed, the contacting conductor (the second connection conductor) covering the bottom surface (i.e., the surface of the second internal conductor thus exposed) and the inside wall surface of the second contact hole and having contact with the second side surface conductor film is formed, thereby realizing the electrical connection between the conductor layer (the second internal conductor) as the second connection electrode section and the second side surface conductor film as the movable electrode.

As an advantage of the case of adopting the connection structure described above, for example, when depositing the second connection conductor, a thick film can be formed inside the contact hole, thus the connection between the respective sections (i.e., the second side surface conductor film, the second connection conductor, and the second internal conductor) can surely be assured, large contact areas between the conductors can be obtained, and it becomes easy to assure the margin (positional margin or the like) in the manufacturing process, as described above. Further, since the proven semiconductor manufacturing process using the contact holes can be used, the connection structure described above also has an advantage that it is superior in stability of manufacturing process.

An electronic device according to another aspect of the invention includes either one of the physical quantity sensors of the aspects of the invention described above.

Since the electronic device according to this aspect of the invention is loaded with either one of the physical quantity sensors described above, a compact electronic device with cost reduction and improvement in performance achieved can be provided.

Specifically, since the capacitance electrodes (the fixed electrode and the movable electrode) of the capacitance element are formed of the conductor films formed on the side surfaces of the insulating structures (the first laminate structure covered with the first side surface insulator and the second laminate structure covered with the second side surface insulator), for example, a special device for electrically separating the conductors different from each other becomes unnecessary, and the manufacturing is possible using the ordinary semiconductor manufacturing technologies without making the manufacturing process complicated, and therefore, the increase in cost of the physical quantity sensor can be prevented. Since the electronic device according to this aspect of the invention is loaded with such a physical quantity sensor, cost reduction can be achieved.

Further, since there is loaded the physical quantity sensor provided with the fine gap between the capacitance electrodes composed of the movable electrode section and the fixed electrode section formed using the semiconductor process, and capable of detecting the fine capacitance variation between the capacitance electrodes, it becomes possible to contribute to provision of the electronic device realizing the highly sensitive physical quantity detection and having improvement in performance achieved.

Further, since the compact physical quantity sensor can be formed by the microfabrication using the semiconductor process, it is possible to contribute to the miniaturization of the electronic device loaded with the physical quantity sensor.

According to another aspect of the invention, there is provided a method of manufacturing an MEMS sensor including the steps of (p) providing a fixation frame section, an elastically deformable section, a movable weight section coupled to the fixation frame section via the elastically deformable section and having a hollow section formed in a periphery, a fixed electrode section fixed to the fixation frame section and including a fixed electrode as one of electrodes of a capacitance element, and a movable electrode section including a movable electrode moving integrally with the movable weight section, disposed so as to be opposed to the fixed electrode section, and constituting the other of the electrodes of the capacitance element, (q) forming a laminate structure in an area including the fixation frame section, the elastically deformable section, the movable weight section, the fixed electrode section, and the movable electrode section by stacking a lower insulating film, a silicon layer, an upper insulating film, and a patterned upper conductor layer on a support substrate, (r) etching anisotropically the silicon layer and the upper insulating film of the laminate structure to form a first hollow section, and separating by the first hollow section the fixation frame section, the elastically deformable section, the movable weight section, a first laminate structure projecting from the fixation frame section, and a second laminate structure formed so as to project from the movable weight section and to be opposed to the first laminate structure from each other in a plan view, (s) etching isotropically the lower insulating film to thereby separate each of the elastically deformable section, the movable weight section, the first laminate structure, and the second laminate structure from the support substrate, (t) forming a first side surface insulating film on a side surface of the first laminate structure along the projection direction, and a second side surface insulating film on a side surface of the second laminate structure along the projection direction and opposed to the first laminate structure, (u) forming a first side surface conductor film as the fixed electrode on the first side surface insulating film, and a second side surface conductor film as the movable electrode on the second side surface insulating film, and (v) forming a first connection electrode section adapted to electrically connect the upper conductor layer and the first side surface conductor film of the first laminate structure to each other to thereby form the fixed electrode section with the first laminate structure, and a second connection electrode section adapted to electrically connect the upper conductor layer and the second side surface conductor film of the second laminate structure to each other to thereby form the movable electrode section with the second laminate structure.

Further, according to another aspect of the invention, there is provided a method of manufacturing a physical quantity sensor, the method including the steps of (a) providing a laminate structure comprising an intermediate layer, a semiconductor layer, and an upper insulating layer stacked on a substrate, (b) providing a first connection electrode section and a second connection electrode section to the upper insulating layer, (c) etching anisotropically the semiconductor layer and the upper insulating layer in a thickness direction to form a first hollow section to thereby defining by the first hollow section a fixation section, a movable weight section, an elastically deformable section connecting the fixation section and the movable weight section, a fixed arm section extending from the fixation section, and a movable arm section extending from the movable weight section, (d) etching isotropically the intermediate layer to form a second hollow section between the substrate and the movable weight section, and between the substrate and the movable arm section, (e) forming a first side surface insulating film on a side surface of the fixed arm section, and a second side surface insulating film on a side surface of the movable arm section, (f) forming a first side surface conductor film on a surface of the first side surface insulating film, a second side surface conductor film on a surface of the second side surface insulating film, a conductor film adapted to electrically connect the first connection electrode section and the first side surface conductor film to each other, and a conductor film adapted to electrically connect the second connection electrode section and the second side surface conductor film to each other, wherein the first side surface conductor film and the second side surface conductor film are disposed so as to be opposed to each other.

Further, according to another aspect of the invention, the physical quantity sensor according to either one of the aspects of the invention can preferably be manufactured.

According to another aspect of the invention, in the method of manufacturing a physical quantity sensor of the above aspect of the invention, the lower insulating film (an intermediate layer) and the upper insulating film (an upper insulating layer) are made of materials different from each other, and in step (d), an etchant with a low selection ratio to the upper insulating film and a high selection ratio to the lower insulating film can be used. According to this configuration, it is prevented that the upper insulating film is unnecessarily etched in the isotropic etching process.

According to another aspect of the invention, in the method of manufacturing a physical quantity sensor of the above aspect of the invention, step (a) includes (a1) stacking the upper insulating film and the upper conductor layer on a silicon-on-insulator (SOI) substrate having the silicon layer stacked on a silicon substrate via a buried insulating layer as the lower insulating film, and in step (d), the buried insulating layer located at the fixation frame section can be kept remaining. According to this configuration, the fixation frame section is supported while being electrically isolated from the silicon substrate, and the fixation frame section can be isolated from the outside.

### BRIEF DESCRIPTION OF THE DRAWINGS

The invention will be described with reference to the accompanying drawings, wherein like numbers reference like elements.

FIG. 1 is a plan view showing a configuration of an example (here, a capacitive acceleration sensor) of a MEMS sensor as a physical quantity sensor according to an embodiment of the invention.

FIG. 2 is a cross-sectional view of the capacitive acceleration sensor shown in FIG. 1.

FIG. 3 is a partial enlarged view of the electrode section shown in FIG. 2.

FIG. 4 is a diagram showing a configuration example of an integrated circuit section (including a detection circuit section) of the capacitive acceleration sensor.

FIGS. 5A through 5C are diagrams for explaining an example of a configuration and an operation of a Q/V conversion circuit.

FIGS. 6A and 6B are diagrams showing a first step of a method of manufacturing the capacitive acceleration sensor.

FIGS. 7A and 7B are diagrams showing a second step of the method of manufacturing the capacitive acceleration sensor.

FIG. 8 is a diagram showing a third step of the method of manufacturing the capacitive acceleration sensor.

FIG. 9 is a diagram showing a fourth step of the method of manufacturing the capacitive acceleration sensor.

FIG. 10 is a diagram showing a fifth step of the method of manufacturing the capacitive acceleration sensor.

FIG. 11 is a diagram showing a sixth step of the method of manufacturing the capacitive acceleration sensor.

FIG. 12 is a plan view showing an example of a capacitive MEMS sensor as a physical quantity sensor of the related art.

FIG. 13 is a plan view showing an example of a capacitive MEMS sensor having increased area efficiency compared to the case shown in FIG. 12.

### DESCRIPTION OF EXEMPLARY EMBODIMENT

Hereinafter, some preferred embodiments of the invention will be described in detail. It should be noted that the present embodiment explained below does not unreasonably limit the content of the invention as set forth in the appended claims, and all of the constituents set forth in the present embodiments are not necessarily essential as means of the invention for solving the problems.

### First Embodiment

### Overall Configuration of Capacitive Acceleration Sensor

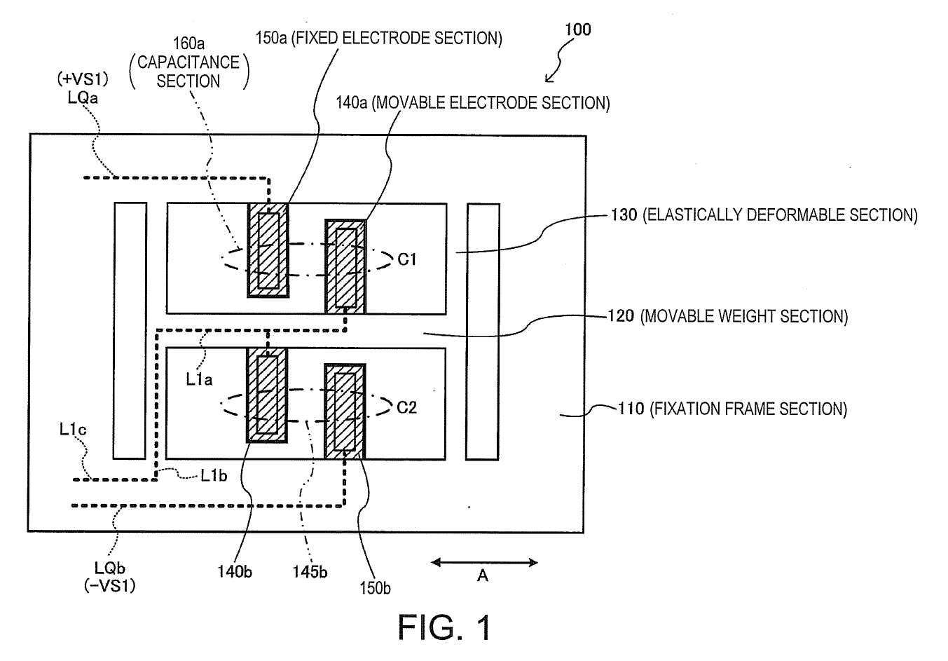

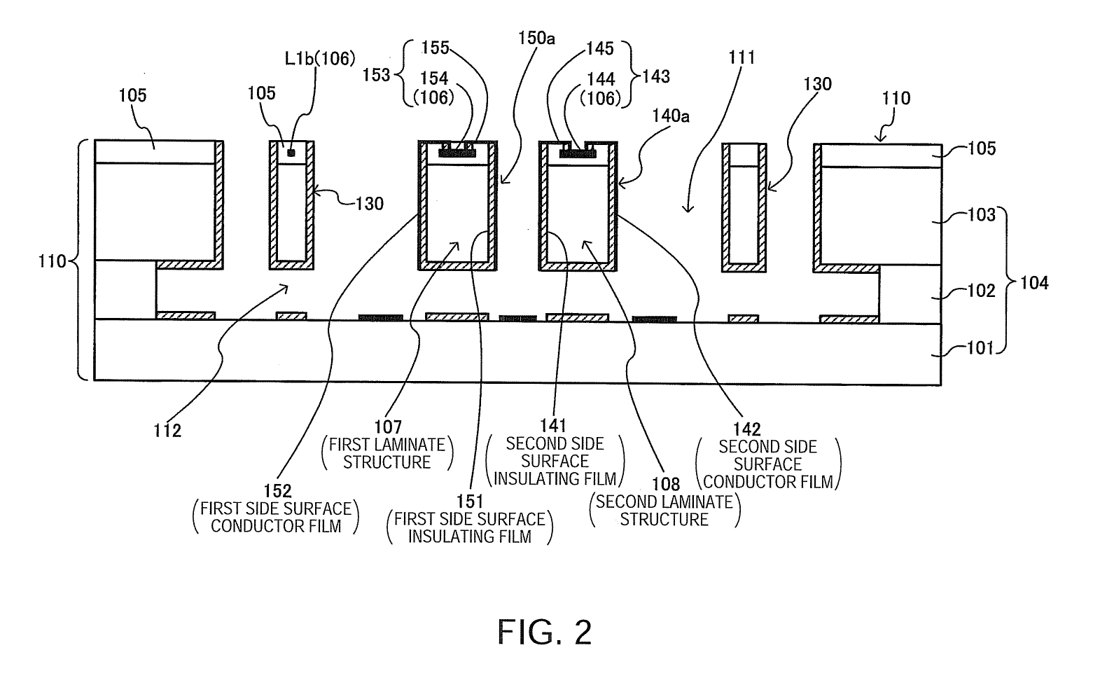

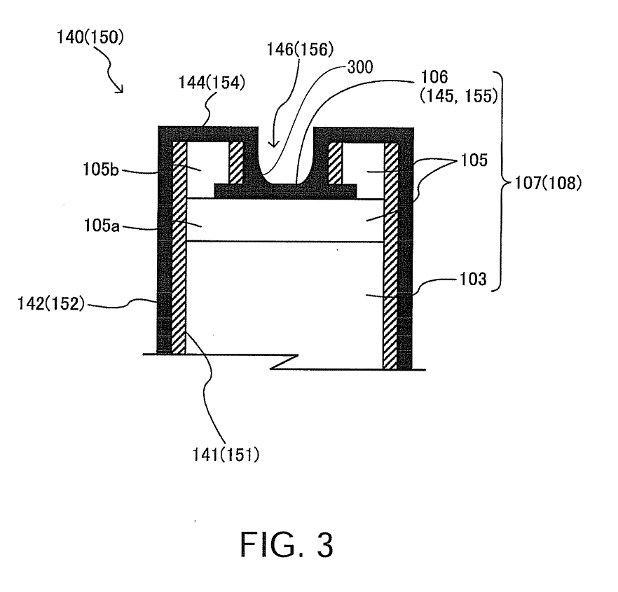

FIG. 1 is a plan view showing a configuration of an example (assumed here to be a capacitive acceleration sensor) of a MEMS sensor as a physical quantity sensor according to an embodiment of the invention. FIG. 2 is a cross-sectional view of the capacitive acceleration sensor shown in FIG. 1. FIG. 3 is a partial enlarged view of electrode sections 140, 150 shown in FIG. 2. It should be noted that the planar layout shown in FIG. 1 is illustrated as the simplest example, and in the present embodiment, the planar layout with high area efficiency shown in FIG. 13 can be adopted.

The capacitive acceleration sensor 100 shown in FIGS. 1 and 2 can be manufactured by forming a laminate structure on a substrate, and then selectively processing the laminate structure using a semiconductor manufacturing technology. For example, there can be used an SOI substrate 104 obtained by stacking an intermediate layer 102 (SiO₂; referred also to as a lower insulating layer or a buried insulating layer) and an active layer (silicon) 103 on a substrate such as a silicon substrate 101. By stacking an upper insulating layer 105 and an upper conductor layer 106 shown in FIG. 3 on the SOI substrate 104, first and second laminate structures 107, 108 are formed. Subsequently, by selectively patterning the first and second laminate structures 107, 108 using, for example, anisotropic dry etching to form a first hollow section 111, then making the etchant for isotropic etching reach the lower insulating layer (e.g., the buried insulating layer 102 of the SOI substrate 104) via the first hollow section 111 to thereby perform the isotropic etching on the lower insulating substrate 102, the structure of the capacitive acceleration sensor 100 can be obtained.

The capacitive acceleration sensor 100 shown in FIG. 1 includes a fixation frame section 110 as a fixation section, elastically deformable sections (spring sections) 130, a movable weight section 120 coupled to the fixation frame section 110 via the elastically deformable sections 130, and having the hollow sections (the first hollow section 111 and a second hollow section 112) formed in the periphery thereof, at least one fixed electrode section 150 (a fixed arm section) (150a, 150b) fixed to the fixation frame section 110 and constituting one of electrodes of capacitance sections 160a, 145b (including a capacitive element C1 or a capacitive element C2), at least one movable electrode section 140 (140a, 140b) moving integrally with the movable weight section 120, and disposed so as to face the fixed electrode section 150, and constituting the other of the electrodes of the capacitance section 160a, 145b (the capacitive element C1 or the capacitive element C2). It should be noted that although in the present embodiment there is explained an example of using the fixation frame section 110 having a frame-like shape as the fixation section of the capacitive acceleration sensor 100, the form of the fixation section is not limited to the frame-like shape, but the fixation section having a shape such as a rectangular shape, or an L-shape obtained by combining rectangular shapes, or a shape including an arc can also be used.

Further, as the capacitance section 160a, 145b (including the capacitance element C1 or the capacitance element C2), the two capacitance sections 160a, 145b, which output detection signals having the absolute values equal to each other and polarities different from each other are provided. Therefore, it is possible to detect the direction in which the acceleration is applied based on the polarities of the signals obtained from the two capacitance sections 160a, 145b. The capacitance section 160a has the fixed electrode section 150a and the movable electrode section 140a disposed so as to be opposed to each other. The capacitance element C1 is composed of the fixed electrode section 150a and the movable electrode section 140a. Similarly, the capacitance section 145b has the fixed electrode section 150b and the movable electrode section 140b disposed so as to be opposed to each other. The capacitance element C2 is composed of the fixed electrode section 150b and the movable electrode section 140b.

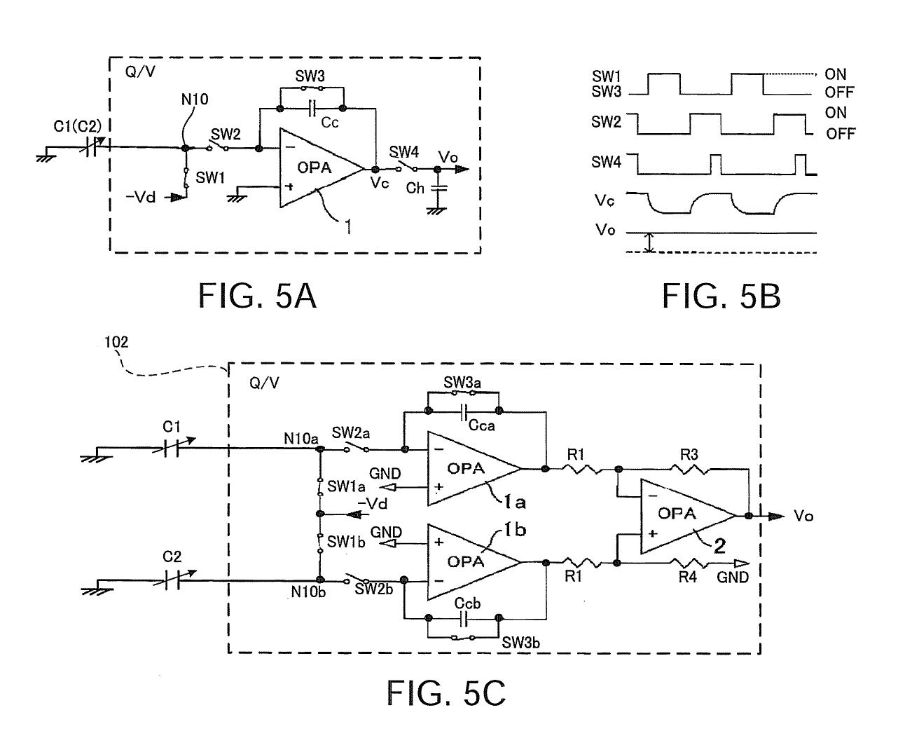

In the example shown in FIG. 1, the movable electrodes 140 are connected to a reference potential (GND, here), and the fixed electrode sections 150 are respectively provided with predetermined potentials (≠GND), wherein the fixed electrode sections 150 become the output electrodes of the detection signals. It should be noted that the configuration described above is only an example, and it is also possible to connect the fixed electrode to the GND, and make the movable electrode function be the output electrode of the detection signal. The potential difference between the movable electrode and the fixed electrode is, for example, Vd (see FIGS. 5A and 5C). Further, in FIG. 1, as the GND wiring line (also referred to as common wiring line in some cases) there are provided first wiring line L1a (the wiring line disposed inside the movable weight section 120), second wiring line L1b (the wiring line disposed along the elastically deformable section 130), and third wiring line L1c (the wiring line disposed on the fixed frame section 110).

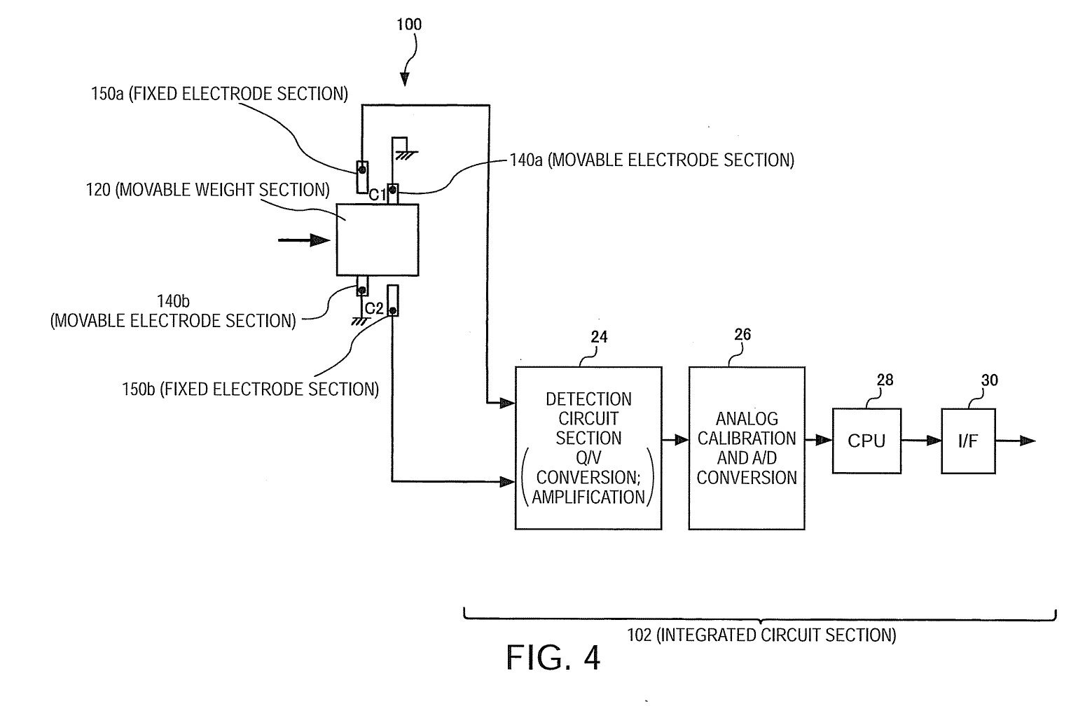

Further, in order for transmitting the detection signals (+VS1 and −VS1) output from the fixed electrode sections 150 (150a, 150b) to a circuit section (a detection circuit section 24 shown in FIG. 4) not shown in the drawing, there are disposed detection signal wiring lines (signal output wiring lines) LQa, LQb.

The first through the third wiring lines L1a through L1c and detection signal wiring lines LQa, LQb can be formed of an upper conductor layer 106 described later.

The movable electrode sections 140 are configured integrally with the movable weight section 120, and vibrates accordingly when the movable weight section 120 vibrates in response to the force caused by acceleration (it should be noted that in FIG. 1, the movable direction of the movable weight section 120 is indicated by the arrow A). In accordance thereto, the gaps (d) of the respective capacitance sections 160a, 145b (the capacitance elements C1, C2) are varied to vary the capacitance values of the respective capacitance sections 160a, 145b (the capacitance elements C1, C2), and thus the migration of the charge is caused in accordance thereto. The value of the acceleration (a physical quantity) applied to the movable weight section 120 can be detected by amplifying the minute current caused by the migration of the charge by an amplifier circuit included in the detection circuit section 24 (see FIG. 4). Further, as described above, the direction of the acceleration can be detected based on the polarities of the two differential signals (+VS1, −VS1).

It should be noted that although in FIG. 1 the two capacitance elements C1, C2 are respectively formed on the sides of the movable weight section 120 different from each other, the capacitance elements C1, C2 can be formed on the respective sides of the movable weight section 120 using comb teeth electrodes (electrodes each formed so as to be indented like comb teeth). In actuality, in order for forming a capacitance element having a desired capacitance value, tens through hundreds of electrode pairs (each corresponding to a pair of movable and fixed electrodes opposed to each other) are provided.

### Specific Configuration Example of Capacitance Element Section

As is understood from the cross-sectional view shown in FIG. 2 and the enlarged view shown in FIG. 3, the fixed electrode sections 150 (150a, 150b) have a first laminate structure 107 as a base structure, the first laminate structure 107 including the silicon layer 103, an upper insulating layer 105, and an upper conductor layer 106 formed to project from the fixation frame section 110. The movable electrode sections 140 (140a, 140b) also have a second laminate structure 108 as a base structure, the second laminate structure 108 including the silicon layer 103, the upper insulating layer 105, and the upper conductor layer 106 formed to project from the movable weight section 120 and opposed to the respective fixed electrode sections 150.

The fixed electrode sections 150 (150a, 150b) each have a first side surface insulating film 151 formed on a side surface of the first laminate structure 107 along the protruding direction, a first side surface conductor film 152 as a fixed electrode formed on the first side surface insulating film 151, and a first connection electrode section 153 formed including the upper conductor layer 106 of the first laminate structure 107, and electrically connected to the first side surface conductor film 152. The first connection electrode section 153 is connected to the detection signal wiring line (the signal output wiring line) LQa or LQb shown in FIG. 1.

Similarly, the movable electrode sections 140 (140a, 140b) each have a second side surface insulating film 141 formed on a side surface of the second laminate structure 108 along the protruding direction and opposed to the first side surface conductor film 152, a second side surface conductor film 142 as a movable electrode formed on the second side surface insulating film 141, and a second connection electrode section 143 formed including the upper conductor layer 106 of the second laminate structure 108, and electrically connected to the second side surface conductor film 142. The second connection electrode section 143 is connected to the first wiring line L1a disposed inside the movable weight section 120 shown in FIG. 1.

Although the side surface conductor films (the first side surface conductor film 152 and the second side surface conductor film 142) as the capacitance electrodes are formed on the side surfaces of the respective two insulating structures (the first laminate structure 107 covered with the first side surface insulating film 151 and the second laminate structure 108 covered with the second side surface insulating film 141), the side surfaces being opposed to each other, the path for applying direct-current bias between the capacitance electrodes or the path for taking out the detection signal is not assured only by this structure. Therefore, in the present embodiment, the first connection electrode section 153 is disposed on the first laminate structure 107 covered with the first side surface insulating film 151, and similarly, the second connection electrode section 143 is disposed on the second laminate structure 108 covered with the second side surface insulating film 141.

Since the first connection electrode section 153 is electrically connected to the first side surface conductor film 152 as the fixed electrode, it is possible to apply the bias voltage to the first side surface conductor film 152 as the fixed electrode via the first connection electrode section 153. Further, in the case in which the fixed electrode is an output electrode of the detection signal, it is possible to take out the detection signal via the first connection electrode section 153. The first laminate structure 107 has the base member formed of the silicon layer 103, and can be made to be the insulating structure by covering the side surface thereof with the first side surface insulating film 151. Therefore, the first connection electrode section 153 can be provided so as to be isolated from the silicon layer 103 in the first laminate structure 107. Therefore, unlike the fixed electrode formed of the silicon layer itself separated from the fixation frame section as the fixation section as in the case of Document 2, it becomes possible to take out the different potential by the wiring line of the first connection electrode section 153 from the fixed electrode section 150 to the side of the fixation frame section 110, which improves the area efficiency.

Since the second connection electrode section 143 is electrically connected to the second side surface conductor film 142 as the movable electrode, it is possible to apply the bias voltage to the second side surface conductor film 142 as the movable electrode via the second connection electrode section 143. Further, in the case in which the movable electrode is an output electrode of the detection signal, it is possible to take out the detection signal via the second connection electrode section 143. Since the base member of the second laminate structure 108 is formed of the silicon layer 103, and can be made to be the insulating structure by covering the side surface thereof with the second side surface insulating film 141, it is possible to provide the second connection electrode section 143 so as to be isolated from the silicon layer 103.

According to the structure of the present embodiment, the capacitance electrodes (the fixed electrode and the movable electrode) of the capacitance element are composed of the conductor films 152, 142 formed on the side surfaces of the respective insulating structures (the first laminate structure 107 covered with the first side surface insulating film 151 and the second laminate structure 108 covered with the second side surface insulating film 141). The fixed electrode sections 150 and the movable electrode sections 140 each have the insulating structure as the base, and are therefore electrically isolated from each other by their nature. Further, use of the insulating structures makes it easy to dispose a plurality of wiring lines in an electrically isolated manner, and even in the case of disposing other electrodes (electrodes other than the capacitance electrodes) such as connection electrodes, the electrical isolation between the electrodes can be assured. Therefore, the special device for electrically separating the different conductors used in the case of, for example, the silicon based MEMS sensor (e.g., Document 2) becomes unnecessary, and therefore, the manufacturing process can be prevented from being complicated. Further, since the structures can be manufactured using an ordinary semiconductor manufacturing technology such as anisotropic etching of silicon, an increase in cost can be prevented. Further, for example, the gap (inter-electrode distance) between the capacitance electrodes is determined in accordance with the thickness of the insulating film and the conductor film formed on the sidewall thereof after patterning (anisotropic etching of the silicon) of the laminate structure, and therefore, it is possible to sufficiently narrow the gap between the capacitance electrodes without depending only on the patterning accuracy. This feature is advantageous for improving the sensitivity of a sensor, and leads to reduction of the chip area.

### First and Second Connection Electrode Sections

As shown in FIGS. 2 and 3, the first connection electrode section 153 can include the upper insulating layer (a first upper insulating layer) 105 of the first laminate structure 107, a first internal conductor 155 formed of the upper conductor layer 106 disposed inside the first upper insulating layer 105, and a first connection conductor 154 covering the inner wall surface of the first laminate structure 107 provided with the first contact hole 156 formed so as to expose at least a part of the surface of the first internal conductor 155, covering the surface of the first internal conductor 155 exposed to the first contact hole 156, and being connected to the first side surface conductor film 152 as the fixed electrode.

Similarly, the second connection electrode section 143 can include the upper insulating layer (a second upper insulating layer) 105 of the second laminate structure 108, a second internal conductor 145 formed of the upper conductor layer 106 disposed inside the second upper insulating layer 105, and a second connection conductor 144 covering the inner wall surface of the second laminate structure 108 provided with the second contact hole 146 formed so as to expose at least a part of the surface of the second internal conductor 145, covering the surface of the second internal conductor 145 exposed to the second contact hole 146, and being connected to the second side surface conductor film 142 as the movable electrode.

As advantages of adopting the connection structure described above, there can be cited various points such as when depositing the first connection conductor 154 and the second connection conductor 144, for example, the internal bottom surfaces of the contact holes 146, 156 can be formed (a bowl-like shape in the drawing) to provide large thickness, the connection between the sections (i.e., between the first side surface conductor film 152, the first connection conductor 154, and the first internal conductor 155, or between the second side surface conductor film 142, the second connection conductor 144, and the second internal conductor 145) can surely be assured, a large contact surface 300 can be obtained between the conductors, or it is easy to assure the margin (positional margin or the like) in the manufacturing process. Further, since the proven semiconductor manufacturing process using the contact holes 146, 156 can be used, the connection structure described above also has an advantage that it is superior in stability of manufacturing process.

### Fixation Frame Section

The area of the fixation frame section 110 as the fixation section of the capacitive acceleration sensor 100 can be formed of a silicon substrate 101 having the silicon layer 103 at least on the lower insulating layer 102. According to this configuration, in the area of the elastically deformable section 130 and the movable electrode section 140, the lower insulating layer 102 is removed, and the second hollow section 112 as a part of the hollow section can be formed. Further, owing to the lower insulating layer 102, the silicon layer 103 of the fixation frame section 110 can be isolated from the outside. It should be noted that the insulating film remaining on the surfaces of the fixation frame section 110 exposed respectively to the first and second hollow sections 111, 112 is formed when forming the first and second side surface insulating films 151, 141, and is therefore not essential.

In the embodiment shown in FIGS. 1 and 2, the fixation frame section 110 as the fixation section is formed of the laminate structure composed of the silicon substrate 101, the lower insulating layer (the buried insulating layer) 102, the silicon layer 103, and the upper insulating layer 105. The third wiring line L1c and the detection signal wiring lines LQa, LQb inside the fixation frame section 110 can be formed of the upper conductor layer 106 inside the upper insulating layer 105.

### Elastically Deformable Section

The elastically deformable section 130 is formed of the laminate structure of the silicon layer 103 and the upper insulating layer 105. Further, as shown in FIG. 2, the first wiring line L1a inside the elastically deformable section 130 shown in FIG. 1 can be formed of the upper conductor layer 106 inside the upper insulating layer 105. It should be noted that the insulating film remaining on the surfaces of the elastically deformable section 130 exposed respectively to the first and second hollow sections 111, 112 is formed when forming the first and second side surface insulating films 151, 141, and is therefore not essential.

### Regarding Configuration Example of Circuit Section for Capacitive Acceleration Sensor

FIG. 4 is a diagram showing a configuration example of a circuit section for the capacitive acceleration sensor. The capacitive acceleration sensor 100 has at least two pairs of movable and fixed electrodes. In FIG. 4, there are provided first movable electrode section 140a and the second movable electrode section 140b, the first fixed electrode section 150a and the second fixed electrode section 150b. The first capacitance element (a first variable capacitor) C1 is composed of the first movable electrode section 140a and the first fixed electrode section 150a. The second capacitance element (a second variable capacitor) C2 is composed of the second movable electrode section 140b and the second fixed electrode section 150b. The potential of one (the movable electrode section) of the electrode sections in each of the first and second capacitance elements C1, C2 is fixed to a reference potential (e.g., the ground potential). It should be noted that it is also possible to connect the potential of the fixed electrode section to the reference potential (e.g., the ground potential).

The detection circuit section 24 can include an amplifier circuit SA, an analog calibration and A/D conversion circuit unit 26, a central processing unit (CPU) 28, and an interface (I/F) circuit 30. It should be noted that this configuration is nothing more than an example, and the invention is not limited to this configuration. For example, the CPU 28 can be replaced with a control logic circuit, and the A/D conversion circuit can also be disposed in the output stage of the amplifier circuit SA provided to the detection circuit section 24.

When the acceleration acts on the movable weight section 120 at rest, then the force due to the acceleration acts on the movable weight section 120, and the gaps of the respective pairs of movable and fixed electrodes are varied. If the movable weight section 120 migrates in the arrow direction shown in FIG. 4, the gap between the first movable electrode section 140a and the first fixed electrode section 150a increases while the gap between the second movable electrode section 140b and the second fixed electrode section 150b decreases. Since the gap and the capacitance have an inversely proportional relationship, the capacitance value C1 of the first capacitance element C1 composed of the first movable electrode section 140a and the first fixed electrode section 150a decreases, while the capacitance value C2 of the second capacitance element C2 composed of the second movable electrode section 140b and the second fixed electrode section 150b increases.

The migration of the charge is caused in accordance with the variation of the capacitance values of the first and second capacitance elements C1, C2. The detection circuit section 24 has a charge amplifier (a Q/V conversion circuit) using, for example, a switched capacitor, and the charge amplifier converts a minute current signal (a charge signal) caused by the migration of the charge into a voltage signal by a sampling action and an integral (amplifying) action. The voltage signal (i.e., an acceleration detection signal detected by the acceleration sensor) output from the charge amplifier undergoes the calibration process (e.g., an adjustment of the phase and the signal amplitude, and possibly a low-pass filter process in addition thereto) by the analog calibration and A/D conversion circuit unit 26, and is then converted from the analog signal to the digital signal.

Here, an example of the configuration and the operation of the Q/V conversion circuit will be explained with reference to FIGS. 5A through 5C. FIG. 5A is a diagram showing a basic configuration of the Q/V conversion amplifier (the charge amplifier) using the switched capacitor, and FIG. 5B is a diagram showing voltage waveforms in the respective sections of the Q/V conversion amplifier shown in FIG. 5A.

As shown in FIG. 5A, the basic Q/V conversion circuit (Q/V conversion amplifier) has first and second switches SW1, SW2 (constituting the switched capacitor in the input section together with the variable capacitor C1 (or C2)), the operational amplifier (OPA) 1, a feedback capacitor (an integral capacitance) Cc, a third switch SW3 for resetting the feedback capacitor Cc, a fourth switch SW4 for sampling the output voltage Vc of the operational amplifier (OPA) 1, and a holding capacitor Ch.

As shown in FIG. 5B, ON/OFF control of the first switch SW1 and the third switch SW3 is performed using a first clock in an in-phase manner, and ON/OFF control of the second switch SW2 is performed using a second clock having a reverse phase with respect to the first clock. The fourth switch SW4 is turned ON for a short period of time at the end of the period during which the second switch SW2 is kept ON. When the first switch SW1 is turned ON, a predetermined voltage Vd is applied to the both ends of the variable capacitor C1 (C2), and the charge is stored in the variable capacitor C1 (C2). In this case, since the third switch SW3 is in the ON state, the feedback capacitor Cc is in a reset state (the state in which the both ends are shorted). Subsequently, when the first switch SW1 and the third switch SW3 are turned OFF, and the second switch SW2 is turned ON, the both ends of the variable capacitor C1 (C2) are set to be the ground potential, and therefore, the charge stored in the variable capacitor C1 (C2) migrates toward the operational amplifier (OPA) 1. In this case, since the amount of the charge is maintained, Vd·C1 (C2)=Vc·Cc is satisfied, and therefore, (C1/Cc)·Vd is obtained as the output voltage Vc of the operational amplifier (OPA) 1. In other words, the gain of the charge amplifier is determined in accordance with the ratio between the capacitance value of the variable capacitor C1 (or C2) and the capacitance value of the feedback capacitor Cc. Subsequently, when the fourth switch (a sampling switch) SW4 is turned ON, the output voltage Vc of the operational amplifier (OPA) 1 is held by the holding capacitor Ch. The voltage thus held is the voltage V0, and the voltage V0 is regarded as the output voltage of the charge amplifier.

As shown in FIG. 4, the differential signals from the two capacitors, namely the first capacitance element C1 and the second capacitance element C2, are input to the actual detection circuit section 24. In this case, the charge amplifier having such a differential configuration as shown in FIG. 5C can be used as the charge amplifier. In the charge amplifier shown in FIG. 5C, there are provided in the input stage a first switched-capacitor amplifier (SW1a, SW2a, OPA1a, Cca, SW3a) for amplifying the signal from the variable capacitor C1, and a second switched-capacitor amplifier (SW1b, SW2b, OPA1b, Ccb, SW3b) for amplifying the signal from the variable capacitor C2. Then, the respective output signals (the differential signals) of the operational amplifier (OPA) 1a, 1b are input to a differential amplifier (OPA2, resisters R1 through R4) disposed in the output stage. As a result, the output signal Vo thus amplified is output from the operational amplifier (OPA) 2. By using the differential amplifier, there can be obtained an advantage that the base noise (the common-mode noise) can be removed.

It should be noted that the configuration example of the charge amplifier explained hereinabove is illustrative only, and the invention is not limited to this configuration. Further, although the two pairs of movable and fixed electrodes are only illustrated in FIGS. 4 and 5C for the sake of convenience of explanation, the invention is not limited to this example, but the number of pairs of electrodes can be increased in accordance with the value of the capacitance required. In practice, there are provided several tens through several hundreds pairs of electrodes, for example. Further, although in the example described above the capacitance of each of the capacitors (the first and second capacitance elements C1, C2) varies due to the variation of the gap between the electrodes in the two capacitors, namely the first capacitance element C1 and the second capacitance element C2, the invention is not limited thereto, but there can also be adopted the configuration in which the opposed areas of two movable electrodes with respect to one reference electrode vary to thereby vary the capacitances of the two capacitors (the first and second capacitance elements C1, C2) (this configuration is advantageous for the case of, for example, detecting the acceleration acting in the Z-axis direction (the direction perpendicular to the substrate)).

### Method of Manufacturing Capacitance Element

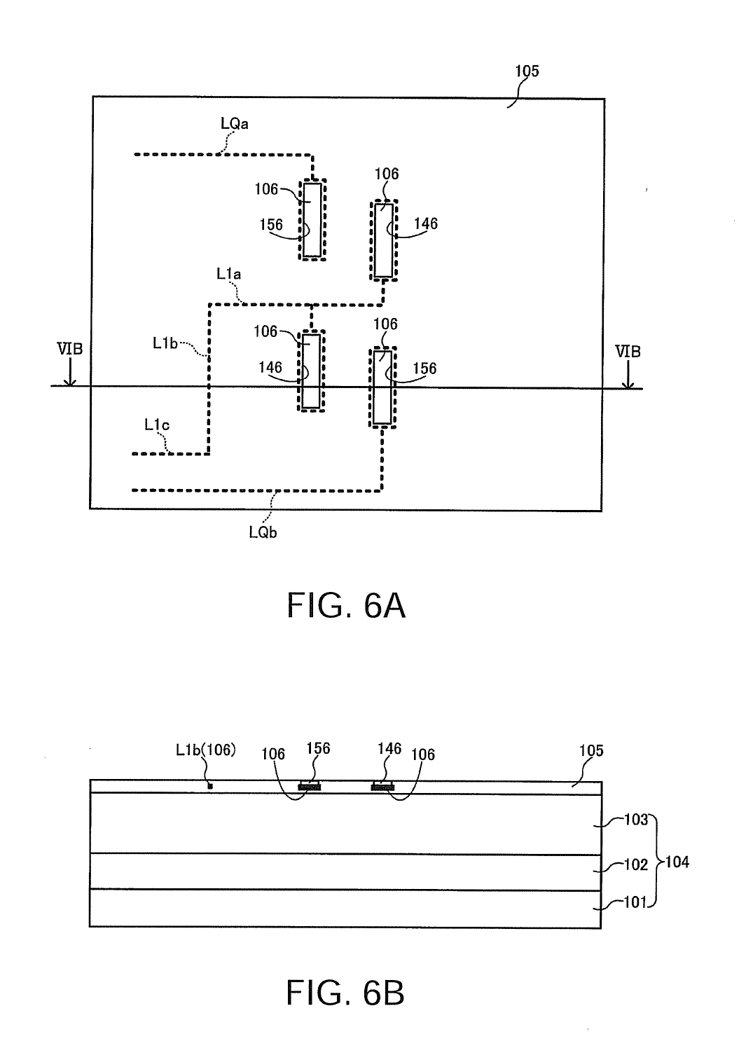

FIGS. 6A, 6B, 7A, 7B, and 8 through 11 are diagrams (cross-sectional views of the device) for explaining the outline of the basic manufacturing process for the capacitive acceleration sensor 100 as an example of the MEMS sensor shown in FIGS. 1 and 2.

A first step shown in FIGS. 6A and 6B corresponds to a step of stacking the lower insulating layer 102, the silicon layer 103, the upper insulating layer 105, and the upper conductor layer 106 to thereby form the laminate structure in the area including the fixation frame section 110 as the fixation section, the movable weight section 120, the elastically deformable section 130, the movable electrode sections 140, and the fixed electrode sections 150.

Specifically, the SOI substrate 104 having the silicon layer 103 stacked on the silicon substrate 101 via the buried insulating layer (the lower insulating layer) 102 is used, and the upper insulating layer 105 and the upper conductor layer 106 are stacked on the SOI substrate 104. The upper insulating layer 105 is different in material from the lower insulating layer 102, and if, for example, the lower insulating layer 102 is made of SiO₂, the upper insulating layer 105 is made of, for example, SiN. Further, the upper conductor layer 106 is formed of a conductive layer made of metal such as A1 or Cu, or a polysilicon layer.

As shown in FIG. 3, the upper insulating layer 105 can be composed of a first upper insulating layer 105a and a second upper insulating layer 105b. The first upper insulating layer 105a is formed first on the silicon layer 103, and then the upper conductor layer 106 is formed thereon. After patterning the upper conductor layer 106, the second upper insulating layer 105b is formed so as to cover the upper conductor layer 106 thus patterned and the first upper insulating layer 105a. In the manner as described above, the upper conductor layer 106 can be formed in the upper insulating layer 105 in a buried manner.

In FIGS. 6A and 6B, the upper insulating layer 105 on the upper conductor layer 106 is provided with the first contact hole 156 and the second contact hole 146 so as to expose the upper conductor layer 106. In the area of the elastically deformable section 130, the second wiring line L1b is formed using the upper conductor layer 106. Other wiring lines shown in FIG. 6A, namely the first wiring line L1a, the third wiring line L1c, and the detection signal wiring lines LQa, LQb, are formed similarly in the respective portions in a buried manner using the upper conductor layer 106.

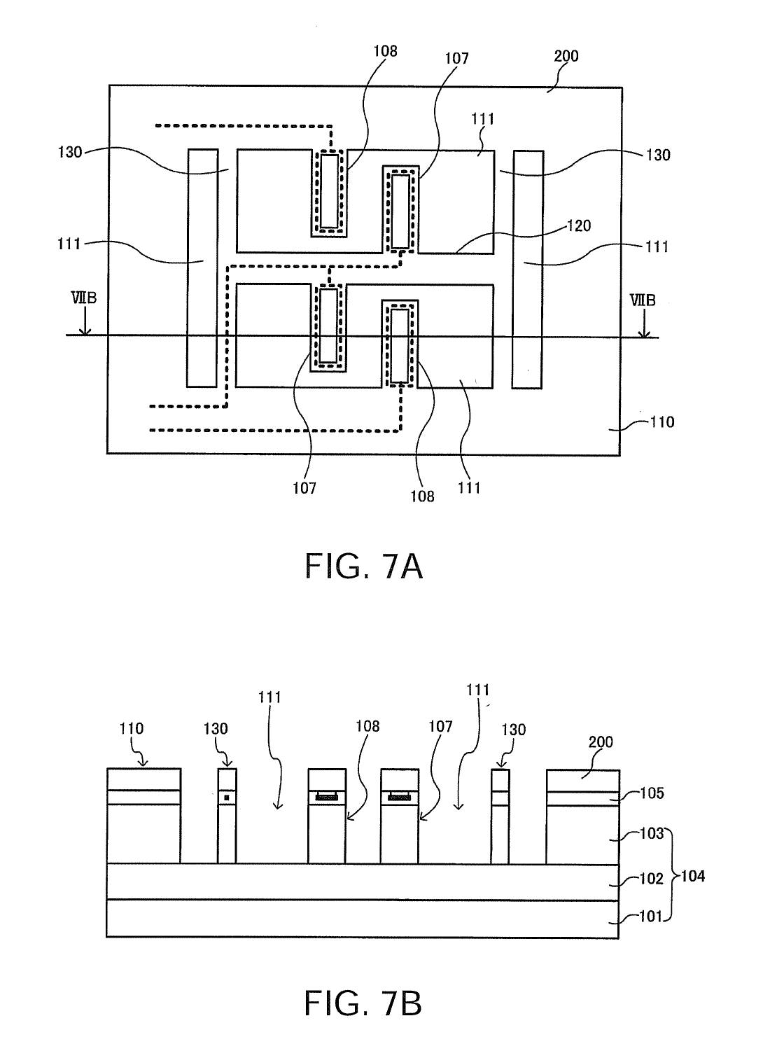

In the second step shown in FIGS. 7A and 7B, the resist 200 is formed on the laminate structure shown in FIG. 6A, and then patterned using an anisotropic etching process to thereby form the first hollow section 111. Due to the patterning process, the silicon layer 103 and the upper insulating layer 105 are etched anisotropically. The upper insulating layer (e.g., SiN) 105 and the silicon layer 103 are different in etchant from each other.

For example, in the case in which the upper insulating layer 105 is made of SiN, a fluorocarbon gas can be cited as the etching gas used for SiN etching. For example, the gas flow rate can be set to CF₄/O₂/N₂=168/192/36 (sccm), and the process pressure can be set to 25 Pa.

As the anisotropic etching method for the silicon layer 103, a method of performing etching while forming the sidewall protecting film, for example, can be used. As an example, the etching method using the inductively coupled plasma (ICP) disclosed in JP-T-2003-505869 can be adopted. In this method, a passivation step (sidewall protecting film formation) and the etching step are repeatedly executed to thereby form a protective film on the sidewall of the hole formed by etching, thus performing the anisotropic etching only in the depth direction while preventing the isotropic etching by the protective film. As etching conditions in the passivation step, it is preferable to use C₄F₈ or C₃F₆ as the etching gas under the process pressure of 5 through 20 μbar and the average input coupled plasma power of 300 through 1,000 W. As etching conditions in the etching step, it is preferable to use SF₆ or ClF₃ as the etching gas under the process pressure of 30 through 50 μbar and the average input coupled plasma power of 1,000 through 5,000 W. Besides the above, reactive ion etching (RIE) for performing the formation of the sidewall protecting film, or alkali etching (wet etching) using KOH can also be used. When performing the anisotropic etching process, the lower insulating layer (the buried insulating layer) 102 functions as the etch-stop layer.

The first hollow section 111 formed by the patterning process separates the fixation frame section 110, the movable weight section 120, the elastically deformable section 130, the first laminate structure 107 projecting from the fixation frame section 110, and the second laminate structure 108 formed so as to project from the movable weight section 120 and opposed to the first laminate structure 107 from each other in a plan view.

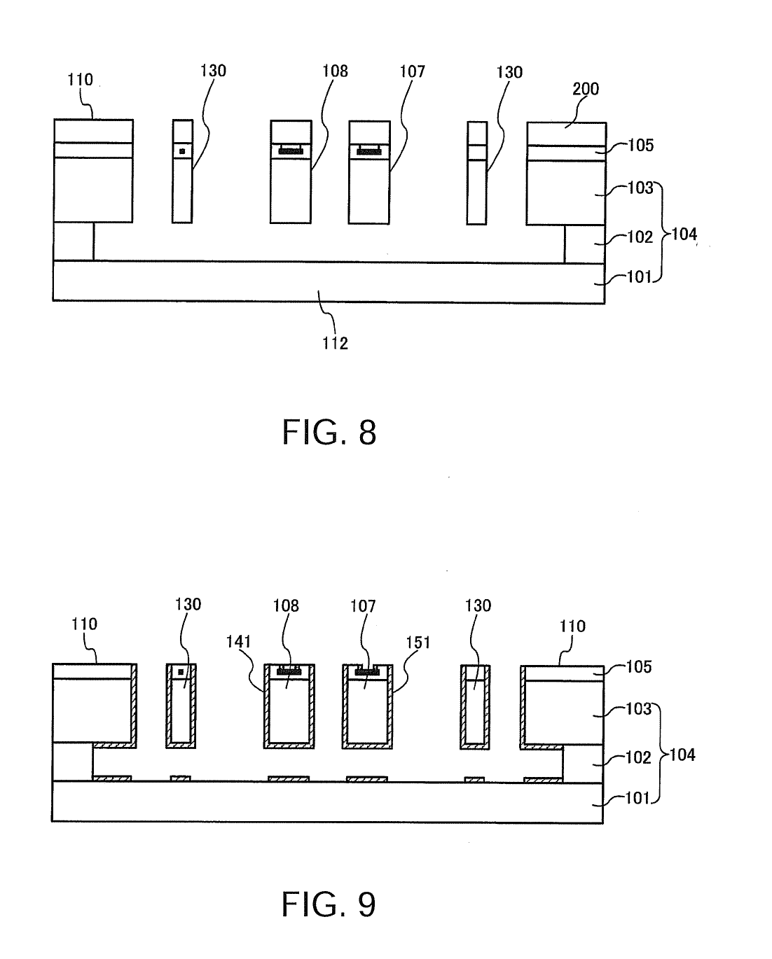

FIG. 8 shows a step of isotropically etching the lower insulating layer (SiO₂) 102 by the dry etching using the vapor of hydrofluoric acid (HF) to thereby separate each of the elastically deformable section 130, the movable weight section 120, the first laminate structure 107, and the second laminate structure 108 from the silicon substrate 101. On this occasion, by making the upper insulating layer 105 and the lower insulating layer 102 different in constituent material from each other, the upper insulating layer 105 can be prevented from being etched.

FIG. 9 shows the step of forming the first side surface insulating film 151 on the side surface of the first laminate structure 107 along the projection direction, and the second side surface insulating film 141 on the side surface of the second laminate structure 108 along the projection direction and opposed to the first side surface insulating film 151. The first side surface insulating film 151 and the second side surface insulating film 141 can be formed by the chemical vapor deposition (CVD) of SiO₂.

It should be noted that although on this occasion the insulating films are also formed on other areas than the first and second laminate structures 107, 108, these insulating films are not essential. Subsequently, the insulating films 151, 141 on the upper surfaces of the first and second laminate structures 107, 108 can be removed by vertical etching (etch-back).

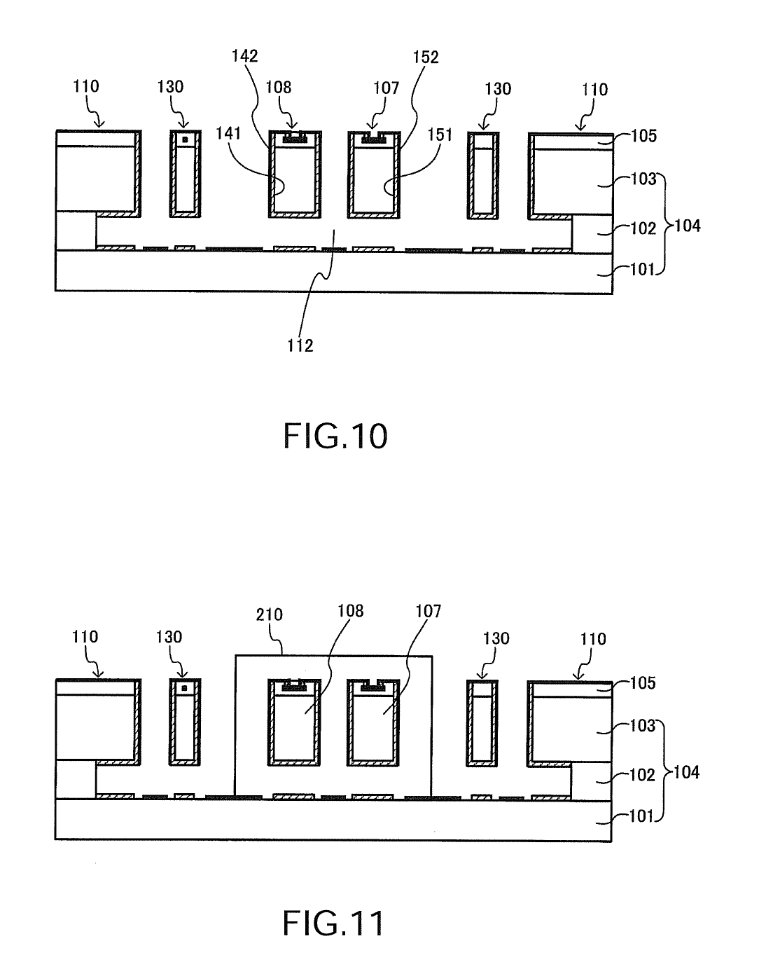

FIG. 10 shows the step of forming the first side surface conductor film 152 as the fixed electrode on the first side surface insulating film 151, and the second side surface conductor film 142 as the movable electrode on the second side surface insulating film 141. In the step shown in FIG. 10, directional sputtering can be used. The directional sputtering is a technology of, for example, aligning the directions of the metal atoms emitted from the target by sputtering, and then forming a metallic layer or a metallic film with the metal atoms having the directions aligned with each other.

As the directional sputtering, an ionized physical vapor deposition (PVD) process, or a long-throw low-pressure sputtering process can be used. The ionized PVD process is sometimes used for forming a film (formation of a barrier metal film) having preferable coverage to high aspect ratio via holes, for example, assures a certain level of deposition rate, and has an advantages of improvement in film quality, deposition with little damage, and so on. The high directivity of the ionized PVD process can be realized by, for example, the metal atoms sputtered from the target, then ionized in the plasma, then accelerated in the sheath on the substrate surface, and then input perpendicularly to the substrate. In order for achieving the high directivity, it is also effective to generate an intensive magnetic field only directly above the target.

Further, the long-throw sputtering process is a sputtering process of suppressing the influence of the reflection angle and of collision with the background atoms to thereby improve the directivity. In the ion beam sputtering process, a noble gas such as argon (Ar) or xenon (Xe) is typically generated with plasma, and then made to collide with the target metal electrode, and then the atoms thus sputtered are made to be deposited on a substrate located on the opposite side. Since the sputtered atoms are scattered isotropically, if the distance between the target electrode and the substrate is short, the sputtered atoms enter the substrate at various angles under the influence of the scattering angles. In order for preventing the problem described above, the distance between the target electrode and the substrate is intentionally increased, and the pressure is reduced, thereby making it possible to prevent the influence of the reflection angle and the influence of the collision with the background atoms. The sputtering process using the method described above and having the directivity is the long-throw sputtering (LTS) process, and when using the long-throw sputtering process, the step coverage can be improved dramatically. It should be noted that the example described above is nothing more than an example, and it is also possible to use other directional sputtering processes.

It should be noted that when depositing the metal film by the directional sputtering process, films are deposited not only on the conductor films 152, 142 of the side surfaces of the first and second laminate structures 107, 108 but also on the upper surfaces of the first and second laminate structures 107, 108, and the inside wall surfaces of the first and second contact holes 156, 146. Therefore, the first and second connection electrode sections 153, 143 can also be formed of these metal films simultaneously. It should be noted that it is also possible to perform the step of forming the first and second side surface conductor layers 152, 142 and the step of forming the first and second connection electrode sections 153, 143 separately from each other.

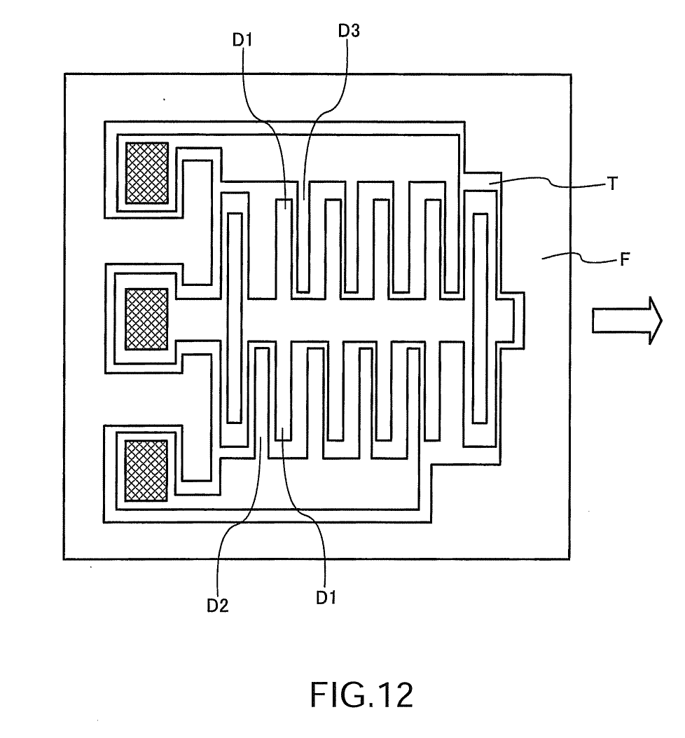

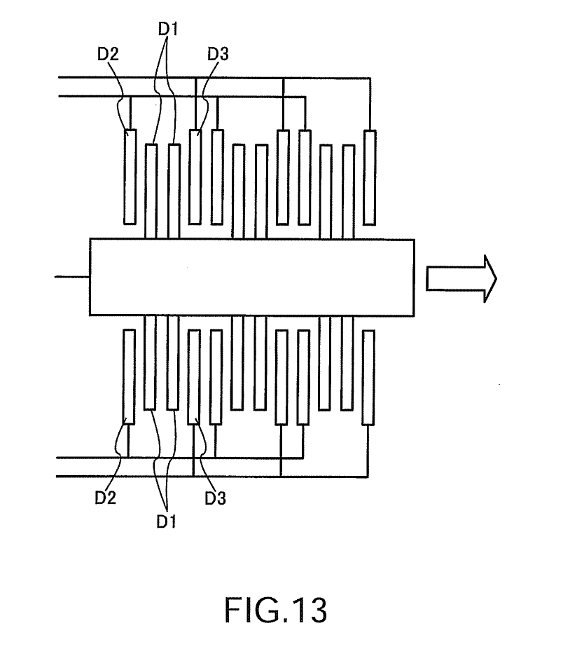

FIG. 11 shows the step of removing the unnecessary conductor films. In order for performing this step, the first and second laminate structures 107, 108 are covered with the resist 210, and the portions not covered with the resist 210 are subject to the etching. For example, the unnecessary conductor films are removed by anisotropic dry etching such as RIE. After the step shown in FIG. 10, the MEMS sensor such as the capacitive acceleration sensor 100 shown in FIGS. 1 and 2 is completed.

Further, for example, the gap (the inter-electrode distance) between the capacitance electrodes is determined in accordance with the patterning accuracy of the insulating layer constituting the laminate structure, and by using presently available microfabrication technologies of the semiconductor field, the gap between the capacitance electrodes can be made sufficiently narrow. This feature is advantageous for improving the sensitivity of a sensor, and leads to reduction of the chip area.

### Electronic Device

In the electronic device equipped with the physical quantity sensor such as the capacitive acceleration sensor 100 according to the embodiment described above, miniaturization, improvement in performance, and cost reduction can be achieved.

As an electronic device in which the physical quantity sensor is installed, there can be cited a global positioning system widely known as GPS, a handheld terminal such as a personal digital assistant (PDA), and a compact electronic device such as a cellular phone and a mobile computer provided with such functions. In such compact electronic devices, a demand for miniaturization and thickness reduction has been increasing in recent years, and at the same time, enhancement of the function and reduction of the cost have also been required. By using the physical quantity sensor, which is manufactured by the manufacturing method according to the embodiment described above, such as the capacitive acceleration sensor 100 in which cost reduction, accuracy improvement, or miniaturization is achieved as the physical quantity sensor installed in these electronic devices, low cost and compact electronic devices in which improvement in performance is achieved can be provided.

Although some embodiments are hereinabove explained, it should easily be understood by those skilled in the art that various modifications not substantially departing from the novel matters and the effects of the invention are possible. Therefore, such modified examples should be included in the scope of the invention. For example, a term described at least once with a different term having a broader sense or the same meaning in the specification or the accompanying drawings can be replaced with the different term in any part of the specification or the accompanying drawings.

For example, the physical quantity sensor (the MEMS sensor) according to the invention is not necessarily limited to those applied to capacitive acceleration sensors, but can also be applied to piezoresistive acceleration sensors. Further, the physical quantity sensor according to the invention can also be applied to any physical sensors for detecting the variation of the capacitance caused by the movement of the movable weight section. The physical quantity sensor according to the invention can be applied to, for example, gyro sensors, or silicon diaphragm pressure sensors. For example, the physical quantity sensor can be applied to the pressure sensor for deforming the silicon diaphragm by the air pressure in the cavity (a hollow chamber), and detecting the variation (or the variation of the resistance value of the piezoresistance) of the capacitance due to the deformation.

Further, if a pair of opposed electrodes having a variable gap (inter-electrode distance) is provided, at least a level of the physical quantity can be detected. It should be noted that the direction in which the physical quantity acts is not detectable with a single capacitance element. Therefore, it is preferable to provide two capacitance elements having the directions of changes of the gaps opposite to each other. Since the signals (i.e., differential signals) having the absolute values equal to each other and the polarities opposite to each other can be obtained respectively from the two capacitance elements, the direction in which the physical quantity (e.g., acceleration) acts can be obtained by determining the polarity of each of the differential signals. Further, the detection axis of the physical quantity is not limited to the uniaxial detection axis or the biaxial detection axis described above, but can be a multiaxial detection axis with three or more axes can also be adopted. Further, it is also possible to adopt a method of detecting the physical quantity using the variation of the opposed area between the electrodes of the capacitor.

The entire disclosure of Japanese Patent Application No. 2009-263651, filed Nov. 19, 2009 and No. 2010-165586, filed Jul. 23, 2010 are expressly incorporated by reference herein.

What is claimed is:

1. A physical quantity sensor comprising:
a fixation section;
an elastically deformable section;
a movable weight section coupled to the fixation section via the elastically deformable section;
a fixed arm section; and
a movable arm section extending from the movable weight section, and disposed so as to be opposed to the fixed arm section,
wherein the fixed arm section and the movable arm section are each a laminate structure obtained by stacking an upper insulating layer on a semiconductor layer,
the fixed arm section includes
a first side surface insulating film disposed on a side surface of the laminate structure,
a first side surface conductor film disposed on a surface of the first side surface insulating film, and
a first connection electrode section provided to the upper insulating layer, and electrically connected to the first side surface conductor film,
the movable arm section includes
a second side surface insulating film disposed on a side surface of the laminate structure,
a second side surface conductor film disposed on a surface of the second side surface insulating film, and
a second connection electrode section provided to the upper insulating layer, and electrically connected to the second side surface conductor film, and
the first side surface conductor film and the second side surface conductor film are disposed so as to be opposed to each other.

2. The physical quantity sensor according to claim 1, wherein
the fixation section includes the semiconductor layer and the upper insulating layer,
an intermediate layer is disposed on the opposite side to the surface of the semiconductor layer on which the upper insulating layer is disposed,
a substrate is disposed on the surface of the intermediate layer on the opposite side to the semiconductor layer side, and
a hollow section is disposed between the substrate and the movable weight section and between the substrate and the movable arm section.

3. The physical quantity sensor according to claim 2, wherein
the intermediate layer is different in material from the upper insulating layer.

4. The physical quantity sensor according to claim 1, wherein
a contact hole is provided to the upper insulating layer,
the first connection electrode section is provided to an inner bottom surface of the contact hole, and
the first connection electrode section and the first side surface conductor film are connected to each other via the contact hole.

5. The physical quantity sensor according to claim 1, wherein
a contact hole is provided to the upper insulating layer,
the second connection electrode section is provided to an inner bottom surface of the contact hole, and
the second connection electrode section and the second side surface conductor film are connected to each other via the contact hole.

6. An electronic device comprising the physical quantity sensor according to claim 1.

7. A method of manufacturing a physical quantity sensor, the method comprising:
(a) providing a laminate structure comprising an intermediate layer, a semiconductor layer, and an upper insulating layer stacked on a substrate;
(b) providing a first connection electrode section and a second connection electrode section to the upper insulating layer;
(c) etching anisotropically the semiconductor layer and the upper insulating layer in a thickness direction to form a first hollow section to thereby defining by the first hollow section a fixation section, a movable weight section, an elastically deformable section connecting the fixation section and the movable weight section, a fixed arm section extending from the fixation section, and a movable arm section extending from the movable weight section;
(d) etching isotropically the intermediate layer to form a second hollow section between the substrate and the movable weight section, and between the substrate and the movable arm section;
(e) forming a first side surface insulating film on a side surface of the fixed arm section, and a second side surface insulating film on a side surface of the movable arm section;
(f) forming a first side surface conductor film on a surface of the first side surface insulating film, a second side surface conductor film on a surface of the second side surface insulating film, a conductor film adapted to electrically connect the first connection electrode section and the first side surface conductor film to each other, and a conductor film adapted to electrically connect the second connection electrode section and the second side surface conductor film to each other,
wherein the first side surface conductor film and the second side surface conductor film are disposed so as to be opposed to each other.
